(19) United States
(12) Patent Application Publication
(10) Pub. No.: US 2010/0208440 A1
(43) Pub. Date: Aug. 19, 2010

(54) PASSIVE ELECTRICAL ARTICLE

(75) Inventors: Joel S. Peiffer, Maplewood, MN (US); Nelson B. O'Bryan, Woodbury, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 12/771,501

(22) Filed: Apr. 30, 2010

Related U.S. Application Data
(62) Division of application No. 11/157,531, filed on Jun. 21, 2005, now abandoned.

(51) Int. Cl. H05K 1/18; H01C 1/012; H01C 17/00

(52) U.S. Cl. 361/763; 338/314; 29/610.1; 361/761

(57) ABSTRACT

A passive electrical article includes a first electrically conductive substrate having a major surface and a second electrically conductive substrate having a major surface. The major surface of the second substrate faces the major surface of the first substrate. An electrically resistive layer is on at least one of the major surface of the first substrate and the major surface of the second substrate. An electrically insulative layer is between the first and second substrates and in contact with the electrically resistive layer. The insulative layer is a polymer having a thickness ranging from about 1 μm to about 20 μm. The insulative layer has a substantially constant thickness.

### CROSS REFERENCE TO RELATED APPLICATIONS

This application is a divisional of U.S. Ser. No. 11/157,531, filed Jun. 21, 2005, the disclosure of which is incorporated by reference in its entirety herein.

### BACKGROUND

A continuing trend in the electronics industry is the miniaturization of electronic circuits and a corresponding increase of the circuit element density of electronic circuits. On conventional printed circuit boards, a large fraction of the board surface area is occupied by surface-mounted passive electrical devices, such as resistors, capacitors and inductors. One way to increase the density of circuit elements in an electronic circuit is to remove passive devices from the surface of the circuit board, and embed or integrate the passive devices into the circuit board itself. This has the added advantage of placing the passive devices much closer to the active circuit components, thus reducing electrical lead length and lead inductance, improving circuit speed, and reducing signal noise. Signal noise can lead to signal integrity and electro-magnetic interference (EMI) issues. Embedding the passive components into the board can reduce the size, thickness and number of layers in the board, which can significantly reduce the cost of the circuit board. The reduction in board size and thickness, as well as the elimination of the surface-mounted components and their associated vias and solder joints, can provide a significant reduction in weight and improved reliability. Finally, as signal rise times, frequencies and current and board densities continue to increase, there is a need for improved thermal dissipation at the printed circuit board level. Thin embedded passive layers can also provide improved thermal dissipation.

### SUMMARY

One aspect of the present invention provides a passive electrical article. In one embodiment, the passive electrical article comprises a first electrically conductive substrate having a major surface and a second electrically conductive substrate having a major surface, the major surface of the second substrate facing the major surface of the first substrate. An electrically resistive layer is on at least one of the major surface of the first substrate and the major surface of the second substrate. An electrically insulative layer is between the first and second substrates and in contact with the electrically resistive layer. The insulative layer comprises a polymer having a thickness ranging from about 1 μm to about 20 μm. The insulative layer has a substantially constant thickness.

Another aspect of the present invention provides a method for forming a passive electrical article. In one embodiment, the method comprises providing a laminate structure comprising a first electrically conductive substrate having a major surface, a second electrically conductive substrate having a major surface, the major surface of the second substrate facing the major surface of the first substrate, an electrically resistive layer on at least one of the major surface of the first substrate and the major surface of the second substrate, and an electrically insulative layer between the first and second substrates and in contact with the electrically resistive layer, the insulative layer comprising a polymer having a thickness ranging from about 1 μm to about 20 μm, wherein the insulative layer has a substantially constant thickness. At least one of the first substrate, the second substrate, and the resistive layer is circuitized to form at least one of a resistor, a capacitor and an inductor.

Another aspect of the present invention provides a printed circuit having a circuitized laminate structure embedded therein. In one embodiment, the laminate structure comprises a first electrically conductive substrate having a major surface, a second electrically conductive substrate having a major surface, the major surface of the second substrate facing the major surface of the first substrate, an electrically resistive layer on at least one of the major surface of the first substrate and the major surface of the second substrate, and an electrically insulative layer between the first and second substrates and in contact with the electrically resistive layer, the insulative layer comprising a polymer having a thickness ranging from about 1 μm to about 20 μm, wherein the insulative layer has a substantially constant thickness.

### BRIEF DESCRIPTION OF THE DRAWINGS

The present invention will be further explained with reference to the appended Figures, wherein like structure is referred to by like numeral throughout the several views, wherein the thickness of layers is not necessarily to scale, and wherein:

FIGS. 1A-1C are cross-sectional views of a passive electrical article of the present invention, which can function as a capacitor, resistor, inductor, or combination thereof.

FIG. 1D is an expanded view of the electrically insulative layer in FIG. 1C.

FIGS. 2A through 2M illustrate an exemplary process for forming a resistor using a passive electrical article according to the present invention.

FIGS. 3A through 3E illustrate exemplary embodiments of a PCB having embedded therein a passive electrical article according to the invention, in which the passive electrical article is patterned to function as a resistor (FIG. 3A), a capacitor (FIGS. 3B and 3C), and an inductor (FIGS. 3D and 3E).

FIGS. 4A through 4F illustrate exemplary embodiments of a passive electrical article having a single resistive layer according to one embodiment of the invention, the article patterned to function as a variety of combinations of passive electrical elements.

FIGS. 5A through 5D illustrate exemplary embodiments of a passive electrical article having two resistive layers according to one embodiment of the invention, the article patterned to function as a variety of combinations of passive electrical elements.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following Detailed Description, therefore, is not to be taken in a limiting sense, and the scope of the present invention is defined by the appended claims.

The present invention is directed to a passive electrical article that can be patterned to function as a capacitor, resistor, inductor, or any combination thereof, and which may be embedded or integrated as a component of a circuit, for example, in a printed circuit board (PCB) or a flexible circuit (flexible circuits are a type of PCB). In addition, the passive electrical article itself, with some modifications, can function as an electrical circuit.

### Passive Electrical Article

One embodiment of a passive electrical article of the present invention comprises a first electrically conductive substrate having a major surface, a second electrically conductive substrate having a major surface facing the major surface of the first substrate, an electrically resistive layer on at least one of the major surface of the first substrate and the major surface of the second substrate, and an electrically insulative layer between the first and second substrates and in contact with the electrically resistive layer. The first substrate, the second substrate, the resistive layer and the insulative layer are selectively patterned to form passive elements including capacitors, resistors, inductors, and combinations thereof. Potential applications for a passive electrical article that functions as a capacitor, resistor, inductor, or any combination thereof according to the present invention are varied, and the range of desired capacitance, resistance, and inductance varies according to the intended application.

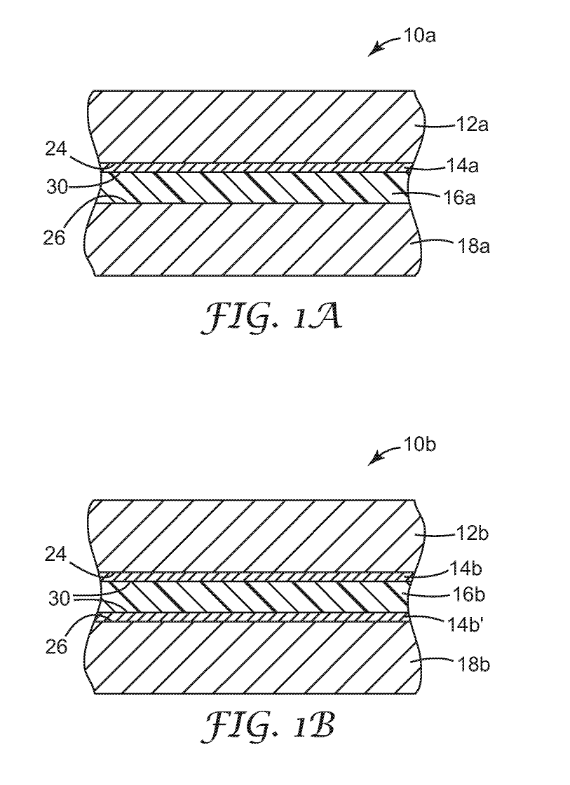

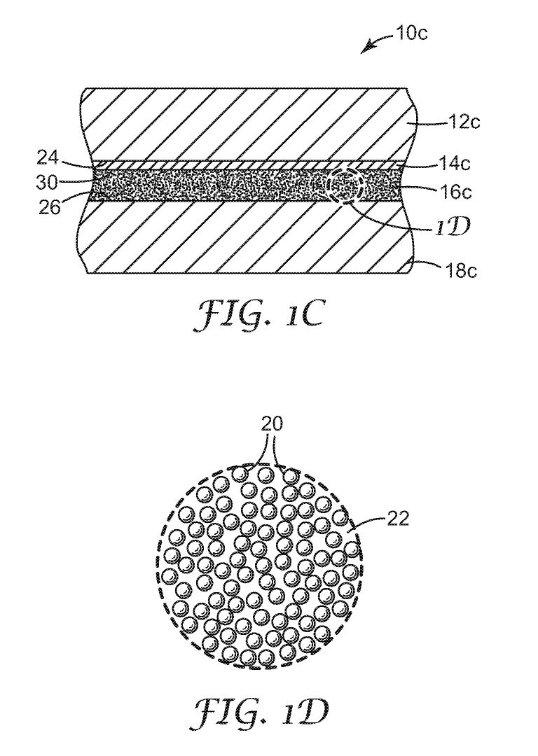

FIGS. 1A-1C illustrate exemplary embodiments of a passive electrical article 10a, 10b, 10c, respectively, according to the present invention that may function as a capacitor, resistor, inductor, or any combination thereof. Referring to FIG. 1A, passive electrical article 10a comprises a laminate of first substrate 12a, electrically resistive layer 14a, electrically insulative layer 16a, and second substrate 18a. Referring to FIG. 1B, passive electrical article 10b is constructed similarly to passive electrical article 10a, but includes an additional electrically resistive layer in the laminate (that may be of a different resistivity), such that a resistive layer is positioned adjacent both substrates. In particular, passive electrical article 10b comprises first substrate 12b, electrically resistive layer 14b, electrically insulative layer 16b, second electrically resistive layer 14b′, and second substrate 18b. Referring now to FIG. 1C, passive electrical article 10c is constructed similarly to passive electrical article 10a. In particular, passive electrical article 10c comprises first substrate 12c, electrically resistive layer 14c, electrically insulative layer 16c, and second substrate 18c. Insulative layer 16c contains a plurality of particles 20 in a polymer 22, as shown in expanded FIG. 1D. The particles 20 may or may not contact each other and may be arrayed in a predetermined manner, for example, uniformly, or randomly, depending on the desired end application. In one embodiment, the particles 20 are substantially spherical in shape, and in another embodiment the particles 20 have other, non-spherical shapes. In one embodiment, the particles 20 have a regular shape and size, and in another embodiment the particles 20 have irregular shapes and/or sizes.

For purposes of clarity and ease of description, unless otherwise specifically noted, passive electrical articles 10a, 10b, 10c, first substrates 12a, 12b, 12c, resistive layers 14a, 14b, 14b′, 14c, insulative layers 16a, 16b, 16c, and second substrates 18a, 18b, 18c, will be referred to herein generally as passive electrical article 10, first substrate 12, resistive layer(s) 14, insulative layer 16, and second substrate 18.

So that the passive electrical article 10 may function as a capacitor, resistor, inductor, or any combination thereof, first substrate 12 and second substrate 18 are conductive. Alternately, at least a major surface 24 of first substrate 12 and a major surface 26 of second substrate 18 are conductive. The resistive layer 14 is also electrically conductive, but is less electrically conductive than the adjacent first or second substrate 12, 18, respectively. The difference in electrical conductivity between first and second substrate 12, 18 and resistive layer 14 may result from differences in material properties and/or dimensions. In one embodiment, the second substrate 18 is not originally included in the lamination comprising the passive electrical article, and instead the second substrate comprises a layer of a printed circuit to which the passive electrical article is joined. In each of the embodiments of FIGS. 1A-1C, insulative layer 16 has a substantially constant thicknesses. In one embodiment, each of the first substrate 12, second substrate 18, resistive layer 14 and insulative layer 16 have substantially constant thicknesses.

In FIGS. 1A-1C, when the passive electrical article 10 is patterned to form a resistor, current flows through the resistive layer 14 in the plane of the resistive layer 14. Current input and output contact pads (not shown) are formed in first substrate 12, and current flows between the contact pads. If a resistive layer 14 is also provided adjacent second substrate 18, a resistor may similarly be formed on the second side of the article. When the passive electrical article 10 is patterned to form a capacitor, opposed capacitive plates (not shown) are formed in first substrate 12 and second substrate 18. In some embodiments, resistive layer(s) 14, which are also conductive, but less so than substrates 12, 18, may extend the capacitive plate beyond the edges of patterned substrates 12, 18. When the passive electrical article 10 is patterned to form an inductor, a coiled structure having input and output contacts (not shown) is formed in one or both of the substrates 12, 18.

The layers of the passive electrical article 10 illustrated in FIGS. 1A-1C are resistant to separation, delamination, or cohesive failure. In one embodiment, a force required to separate the layers or induce cohesive failure of any of the layers of the passive electrical article 10 at a 90 degree peel angle is greater than about 3 pounds/inch (about 0.5 kiloNewtons/meter (kN/m)), preferably greater than 4 pounds/inch (0.7 kN/m), more preferably greater than 6 pounds/inch (1 kN/m), as measured according to the IPC Test Method Manual, IPC-TM-650, test number 2.4.9 dated October 1988, as published by the Institute for Interconnecting and Packaging Electronic Circuits. This force is required to separate any adjacent layers in the laminate comprising the passive electrical article 10, such as a substrate 12, 18 from an adjacent insulative layer 16, a substrate 12, 18 from an adjacent resistive layer 14, or an insulative layer 16 from an adjacent resistive layer 14 or induce cohesive failure within the substrate 12, 18, the resistive layer 14 or the insulative layer 16.

In one embodiment, the article 10 has a capacitance density greater than about 1 nF/in2, preferably greater than about 4 nF/in², more preferably greater than about 10 nF/in².

### Substrate

Substrates 12, 18 of the passive electrical article 10 may comprise a single layer or a plurality of layers, for example, a laminate. Substrates 12, 18 may comprise graphite; composites such as silver particles in a polymer matrix; metal such as copper or aluminum; combinations thereof, or laminates thereof. An example of a multilayer substrate includes copper on polyimide. The first and second substrates 12, 18 may be the same or different in materials and construction.

In accordance with the present invention, at least one of the substrates 12, 18 is a self-supporting substrate. As used herein, the term “self-supporting substrate” refers to a substrate having sufficient structural integrity such that the substrate is capable of being coated and handled without a carrier for support. It is preferable that substrates 12, 18 are flexible; however, rigid substrates may also be used. In one embodiment, the substrates 12, 18 have a thickness ranging from approximately 5 to 80 μm, more preferably approximately 10 to 40 μm. When the ability to spread high thermal loads or handle high currents is required, substrates having a thickness at the higher ranges are preferred, such as a thickness of at least approximately 70 μm.

Typically, a major surface 24 of the first substrate 12 in contact with the electrically resistive layer 14 is electrically conductive, and a major surface 26 of the second substrate 18 in contact with the electrically insulative layer 16 (in FIG. 1A) or the electrically resistive layer 14 (in FIG. 1B) is also electrically conductive. Surface treatment, which adds material to these major surfaces 24, 26 by, for example, oxidation or reaction with a coupling agent, for example, silanes terminated with functional groups, may be used to promote adhesion between adjacent layers. The resulting material on the major surfaces 24, 26 of the substrates 12, 18 themselves may not necessarily be conductive. Specifically, if the major surface is in contact with insulative layer 16 (and not a resistive layer 14), material on the major surface does not have to be conductive, because a capacitor can be formed provided the substrate itself is conductive.

In one embodiment, the major surfaces 24, 26 of the first and second substrates 12, 18 have an average surface roughness ranging from about 10 nm to about 300 nm, preferably 10 nm to 100 nm, more preferably 10 nm to 50 nm. If the electrically insulative layer 16 thickness is 1 μm or less, the average surface roughness preferably ranges from 10 nm to 50 nm. Average surface roughness, RMS, is measured by taking the square root of the average, [(z₁)²+(z₂)²+(z₃)²+ . . . (zₙ)²]/n, where z is a distance above or below the substrate surface mean and n is the number of points measured and is at least 1000. The area measured is at least 0.2 mm². Preferably, no zₙ is greater than half the thickness of the electrically insulative or electrically resistive layer.

When the substrate is a metal, the metal preferably has an anneal temperature which is at or below the temperature for curing the electrically insulative layer 16, or the metal is annealed before the electrically insulative layer 14 is coated.

A preferred substrate is copper. Exemplary copper includes copper foil available from Carl Schlenk, AG, Nurnberg, Germany, or from Olin Corporation's Somers Thin Strip/Brass Group, Waterbury, Conn.

### Electrically Resistive Layer

The electrically resistive layer(s) 14 of the passive electrical article 10 comprises a thin film of high-ohmic material. Exemplary high-ohmic materials include, but are not limited to, nickel-chromium (NiCr), nickel-chromium-aluminum-silicon (NiCrAlSi), nickel-phosphorous (NiP), or doped conductive, such as doped platinum. In one embodiment, the resistive layer(s) 14 are formed from a material having high magnetic permeability, such as a ferrite material, nickel-iron alloys such as permalloy, silicon steel or cobalt alloys. Materials with a relative permeability of greater than 10 are preferred and those with a relative permeability of greater than 100 are more preferred to provide greater inductance when the passive article is patterned to form an inductor. In one embodiment, resistive layer(s) 14 have a thickness less than about 2 μm. In one embodiment, resistive layer(s) 14 have a resistivity greater than about 25 Ohms/Sq, preferably greater than about 250 Ohms/Sq., and more preferably greater than about 500 Ohms/Sq.

In one embodiment, the resistive layer(s) 14 are provided on one or both substrates 12, 18 by sputtering, physical vapor deposition, chemical vapor deposition, electroplating, or any other suitable method known in the art which is suitable for the particular materials of the resistive layer(s) 14 and substrates 12, 18. Suitable resistive layers on copper substrates include copper substrates with integrated thin film resistor, having the trade designations TCR and TCR+ from Gould Electronics Inc., Chandler, Ariz.; INSITE Embedded Resistors from Rohm & Haas Electronic Materials, Marlborough, Mass.; and Ohmega-Ply Resistor-Conductor Material from Ohmega Technologies, Inc., Culver City, Calif.

The surface 30 of resistive layer(s) 14 that interfaces with insulative layer 16 will have surface roughness characteristics similar to the major surfaces 24, 26 of the first and second substrates 12, 18 as described above. In particular, in one embodiment, surface 30 has an average surface roughness ranging from about 10 nm to about 300 nm, preferably 10 nm to 100 nm, more preferably 10 nm to 50 nm. If the electrically insulative layer 16 thickness is 1 μm or less, the average surface roughness preferably ranges from 10 nm to 50 nm. Average surface roughness, RMS, is measured as described above.

### Electrically Insulative Layer

The electrically insulative layer 16 of the passive electrical article 10, which may itself comprise one or more layers, comprises a polymer. Preferably, the electrically insulative layer 16 comprises a polymer and a plurality of particles and is prepared from a blend of resin and particles.

The electrically insulative layer 16, with regard to the surface roughness of substrate material 12, 18 and resistive layer(s) 14, is selected to provide a passive electrical article that requires a force as described above to separate adjacent layers (i.e., a substrate or a resistive layer) from the insulative layer 16.

Suitable resins for the electrically insulative layer 16 include epoxy, polyimide, polyvinylidene fluoride, cyanoethyl pullulan, benzocyclobutene, polynorbornene, polytetrafluoroethylene, acrylates, polyphenylene oxide (PPO), cyanate ester, bismaleimide triazine (BT), allylated polyphenylene ether (APPE), and blends thereof. The organic polymers described in U.S. Patent Publication No. 2004/0222412, commonly assigned herewith and incorporated by reference in its entirety, are further examples of suitable materials for insulative layer 16.

Commercially available epoxies include those available from Resolution Performance Products, Houston, Tex., under the trade designation EPON 1001F and EPON 1050. Preferably, the resin can withstand a temperature that would be encountered in a typical solder reflow operation, for example, in the range of about 180 to about 290° C. These resins may be dried or cured to form the electrically insulative or electrically conducting layer.

Exemplary blends include blends of epoxies, preferably a blend of a diglycidylether of bisphenol A and a novolac epoxy, for example, 90 to 70% by weight EPON 1001F and 10 to 30% by weight EPON 1050 based on the total weight of the resin.

When particles are present, the particles are dielectric (or insulative) particles or conductive particles or mixtures thereof. Particle distribution may be random or ordered. Typically, particles in the insulative layer comprise dielectric or insulative particles. However, mixtures of particles are suitable provided that the overall effect of the resin and particle blend is insulative.

Exemplary dielectric or insulative particles include barium titanate, barium strontium titanate, titanium oxide, lead zirconium titanate, and mixtures thereof. A commercially available barium titanate is available from Nippon Chemical Industrial Co., Tokyo, Japan, under the trade designation AKBT.

The particles may be any shape and may be regularly or irregularly shaped. Exemplary shapes include spheres, platelets, cubes, needles, oblate, spheroids, pyramids, prisms, flakes, rods, plates, fibers, chips, whiskers, and mixtures thereof.

The particle size, i.e., the smallest dimension of the particle, typically ranges from about 0.05 to about 10 μm, preferably 0.05 to 5 μm, more preferably 0.05 to 2 μm. Preferably, the particles have a size allowing at least two to three particles to be stacked vertically within the electrically insulative layer thickness. A relatively large particle having a particle size slightly larger than the thickness of the electrically insulative layer undesirably allows individual particles to bridge the gap between layers on either side of the insulative layer. During lamination, these relatively large particles will cause a compressive force leading to surface deformation and a “wiping” action at the particle-substrate interface or the particle-resistive layer interface, which may remove surface oxide layers.

The loading of particles in the polymer is typically 20 to 70% by volume, preferably 30 to 60% by volume, more preferably 40 to 50% by volume, based on the total volume of the electrically insulative layer.

In one embodiment, the thickness of the electrically insulative layer 16 (comprising one or more layers) ranges from about 1 to about 20 μm. In another embodiment, the thickness of the electrically insulative layer 16 ranges from about 8 to about 16 μm.

In one embodiment, the dielectric constant of the insulative layer 16 is greater than about 4, preferably greater than about 11, more preferably greater than about 15.

In one embodiment, the insulative layer 16 has a thermal conductivity greater than about 0.2 W/m-K, preferably greater than about 0.35 W/m-K, more preferably greater than about 0.5 W/m-K.

### Method of Manufacturing a Passive Electrical Article

A method for manufacturing a passive electrical article 10 in accordance with the present invention comprises providing a first substrate 12 having a major surface 24 substantially free of debris or chemisorbed or adsorbed materials, and providing a resistive layer 14 on at least the major surface 24 of first substrate 12. The resistive layer 14 may be provided on the major surface 24 by sputtering, physical or chemical vapor deposition, electroplating, or any other suitable method known in the art. A blend comprising a resin is provided and coated onto the surface 30 of the resistive layer 14, and a major surface 26 of a second substrate 18 is laminated to the blend. The blend is then cured or dried. Alternatively, the blend may be coated on the major surface 26 of the second substrate 18, and the blend-coated surface 26 of the second substrate 18 laminated to the surface 30 of the resistive layer 14 on the first substrate 12. Alternatively, the blend may be coated on the surface 30 of resistive layer 14 and on the major surface 26 of the second substrate 18, and the blend-coated surfaces 30, 26 laminated together. It will be recognized that the above method for manufacturing a passive electrical article 10 results in the embodiment illustrated in FIG. 1C. In other embodiments, a resistive layer 14 can also be provided on the major surface 26 of second substrate 18, and/or a different material may be used to form insulative layer 16, so as to form the passive electrical article of FIG. 1A or 1B.

The substrates 12, 18 are preferably substantially free of debris or chemisorbed or adsorbed materials in order to maximize adhesion with the electrically resistive layer 14 and the electrically insulative layer 16. This is achieved, for example, by reducing the amount of residual organics on the substrate surfaces 24, 26 and removing debris from the substrate surface 24, 26. Exemplary methods include surface treatment as described below.

The steps of the present invention are described in additional detail with reference to copper foil as the first and second substrates 12, 18, a doped platinum as the resistive layer 14, and electrically insulative layer 16 formed from epoxy and barium titanate particles.

A copper foil is provided for the first and second substrates 12, 18. The copper foil of the first substrate 12 is previously coated with a doped platinum resistor layer 14 (INSITE Resistor Material from Rohm & Haas Electronic Materials, Marlborough, Mass.). The copper foil substrates 12, 18 and doped platinum resistive layer 14, which may have material present on their exposed surfaces such as an organic anti-corrosion agent (for example, a benzotriazole derivative) and/or residual oils from the rolling process, are subjected to a surface treatment, for example, to ensure good adhesion between the electrically insulative layer 16 and the surface 30 of doped platinum resistive layer 14 on the first copper foil substrate 12, and also between the insulative layer 16 and the surface 26 of the second copper foil substrate 18. Removal can be effected by, for example, treating the copper foil substrate and/or doped platinum resistor layer with an argon-oxygen plasma or with an air corona, or wet chemical treatment can be used as is well understood in the art. Particulates adhering to the exposed surfaces of the copper foil substrates and doped platinum resistive layer can be removed using, for example, an ultrasonic/vacuum web cleaning device commercially available from Web Systems Inc., Boulder, Colo., under the trade designation ULTRACLEANER. Preferably, the copper foils and resistive layer are not scratched, dented, or bent during this surface treatment step in order to avoid possible coating problems and coating defects which may result in non-uniform coating or shorted articles, such as shorted capacitors.

The blend to be used for insulative layer 16 may be prepared by providing a resin such as epoxy, optionally a plurality of dielectric or insulative particles such a barium titanate, and optionally a catalyst. Adsorbed water or residual materials on the particles; e.g., carbonates, resulting from the manufacturing process can be removed from the surface of the particles before use. Removal may be accomplished by heating the particles in air at a particular temperature for a certain period of time, for example, 350° C. for 15 hours. After heating, the particles may be stored in a dessicator before use in the blend.

The blend of barium titanate particles and epoxy may be prepared as follows. Barium titanate particles are first mixed with a ketone solvent containing a dispersant. Common mixing equipment can be a propeller stirrer. The weight ratios of components are typically 85% barium titanate, 13.5% solvent, and 1.5% dispersant. To complete the dispersion and break agglomerates, the mixture can be milled with a homogenizer such as a Gaulin homogenizer sold by APV, Lake Mills, Wis. The concentrated dispersion is filtered to remove undispersed particles. Typically, the final filter in the series is a 10 micron absolute filter. This filtered, concentrated dispersion can subsequently be blended with epoxy polymer solutions and other additives to produce a dispersion blend suitable for coating. Preferably, the final coating dispersion is filtered again just prior to the coating operation.

The blend may contain additives such as a dispersant, preferably a nonionic dispersant, and solvents. Examples of dispersants include, for example, a copolymer of polyester and polyamine, commercially available from Avecia Pigments & Additives, Manchester, UK under the trade designation SOLSPERSE 24000. Examples of solvents, for example, include methyl ethyl ketone and methyl isobutyl ketone, both of which are commercially available from Aldrich Chemical, Milwaukee, Wis. In the preferred system, other additives are not required; however, additional components such as agents to change viscosity or to produce a level coating can be used.

A catalyst or curing agent may be added to the blend. If a catalyst or curing agent is used, the catalyst or curing agent can be added before the coating step. Preferably, the catalyst or curing agent is added just before the coating step.

Exemplary catalysts include amines and imidazoles. If particles having a basic surface, i.e., having a pH of greater than 7, are not present, then exemplary catalysts can include those producing acidic species, i.e., having a pH of less than 7, such as sulfonium salts. A commercially available catalyst is 2,4,6-tris(dimethylaminomethyl)phenol commercially available from Aldrich Chemical Milwaukee, Wis. Typically, a catalyst is used in an amount ranging from about 0.5 to about 8% by weight, preferably 0.5 to 1.5%, based on the weight of resin. When 2,4,6-tris(dimethylaminomethyl)phenol is used, the % by weight based on the weight of resin is preferably 0.5 to 1%.

Exemplary curing agents include polyamines, polyamides, polyphenols and derivatives thereof. A commercially available curing agent is 1,3-phenylenediamine, commercially available from E. I. DuPont de Nemours Company, Wilmington, Del. Typically, a curing agent is used in an amount ranging from about 10 to about 100% by weight, preferably 10 to 50% by weight, based on the weight of resin.

The surface 30 of cleaned doped platinum resistive layer 14 and the surface 26 of cleaned copper foil substrate 18 are coated with the blend using any suitable method, for example, a gravure coater. Preferably, coating is performed in a cleanroom to minimize contamination. The dry thickness of the coating depends on the percent solids in the blend, the relative speeds of the gravure roll and the coating substrate, and on the cell volume of the gravure used. Typically, to achieve a dry thickness in the range of about 0.5 to about 10 μm, the percent solids are in the range of 20 to 60% by weight. The coating is dried to a tack-free state in the oven of the coater, typically at a temperature of less than about 100° C., preferably the coating is dried in stages starting with a temperature of about 30° C. and ending with a temperature of about 100° C., and then wound onto a roll. Higher final drying temperatures, e.g., up to about 200° C. can be used, but are not required. Generally, very little cross-linking occurs during the drying step; its purpose is primarily to remove as much solvent as possible. Retained solvent may lead to blocking (i.e., unwanted interlayer adhesion) when the coating is stored on a roll and to poor adhesion for the laminate.

Coating techniques to avoid defects include in-line filtration and deaeration (to remove air bubbles) of the coating mixture. In one implementation, before laminating two substrates coated with an electrically insulative layer, at least one of the electrically insulative layers is partially cured, preferably in air, if a resin requiring curing is used. In particular, adhesion of the substrate may be improved by heat treating the coating before lamination. The time for heat treatment is preferably short, for example, less than about 10 minutes, particularly at higher temperatures.

Lamination of the electrically insulative layer coated surfaces 26, 30 is carried out by sending one or both of the substrates 12, 18 with insulative coating thereon through an oven before reaching the laminator, for example, at a temperature ranging from about 5 to 25° C. below the lamination temperature. Preferably, the electrically insulative layer should not touch anything during lamination and lamination should be done in a cleanroom. To make a passive electrical article of the present invention, the coated substrates are laminated, electrically insulative layer to electrically insulative layer, using a laminator with two nip rollers heated to a temperature ranging from about 150 to about 200° C., preferably about 150° C. Suitable air pressure is supplied to the laminator rolls, preferably at a pressure ranging from 5 to 40 psi (34 to 280 kPa), preferably 15 psi (100 kPa). The roller speed can be set at any suitable value and preferably ranges from 12 to 72 inches/minute (0.5 to 3.0 cm/second), more preferably 15 to 36 inches/minute (0.64 to 1.5 cm/second). This process can be conducted in a batch mode as well.

The laminated material can be cut into sheets of the desired length or wound onto a suitable core. Once lamination is complete, the preferred cleanroom facilities are no longer required.

When the resin requires curing, the laminated material is then cured. Exemplary curing temperatures include temperatures ranging from about 140 to about 200° C., preferably 160 to 190° C. and exemplary curing times include a period ranging from about 60 to about 180 minutes, preferably 60 to 100 minutes.

Adhesion of the electrically insulative layer 16 to surface 30 of doped platinum resistive layer 14 and surface 26 of copper foil 18 may be enhanced if the metal is sufficiently soft at the time of coating or becomes soft during lamination and/or cure; i.e., the foil and/or resistive layer is annealed before coating or becomes annealed during subsequent processing. Annealing may be accomplished by heating before the coating step or as a result of the curing or drying step if the metal anneal temperature is at or lower than the cure temperature of the resin. It is preferred to use a metal substrate with an anneal temperature below the temperature at which curing or drying and lamination occur Annealing conditions will vary depending on the metal substrate used. Preferably, in the case of copper, at either of these stages in the process, the metal substrate obtains a Vickers hardness, using a 10 g load, of less than about 75 kg/mm². A preferred temperature range for copper to achieve this hardness ranges from about 100 to about 180° C., more preferably 120 to 160° C.

Although a passive electrical article of the present invention can be functional as it is fabricated, the passive electrical article may preferably be patterned as described below, for example, to form discrete islands or removed regions in order to limit lateral conductivity. The patterned passive electrical article may be used as a circuit article itself or as a component in a circuit article, as described below.

### Patterning

Resistor, capacitor and inductor elements can be created by patterning first substrate 12, second substrate 18 or resistive layer 14. Other features such as circuit traces including those that connect resistor, capacitor or inductive elements, through hole contact pads and through hole clearances (where no electrical connection is desired) can also be created by patterning first substrate 12, second substrate 18, resistive layer 14 or insulative layer 16. It should be noted that the use of the phrase “through hole” is being used as a general term to include all vertical interconnect geometries such as through holes, buried vias and blind vias for example.

Any suitable patterning technique known in the art may be employed. For example, patterning of the passive electrical article may be performed by photolithography and/or by laser ablation as is well known in the art.

Photolithography of the substrates 12, 18 may be performed by applying a photoresist to the passive electrical article, which is then exposed and developed to form a pattern of concealed and exposed substrate areas on the passive electrical article. If the passive electrical article is then exposed to a solution known to chemically attack or etch the substrate, selected areas of the substrate can be removed. A stripping agent, such as potassium hydroxide, is then employed to remove the remaining areas of photoresist. This process allows areas of substrate to be removed that are not desired in the circuit structure.

In areas where the substrate 12 and resistive layer 14 are both to be removed, the resistive layer 14 can be etched immediately after substrate 12 if desired. For some resistive materials, it will be possible to use the same etchant for substrate layer 12 and resistive layer 14.

An identical or similar photolighography process may be performed to pattern resistive layer 14. Photolithography of the resistive layer 14 may be performed by applying a photoresist to the passive electrical article already having a portion of resistive layer 14 exposed (such as by photolithography of the substrate 12). This process allows areas of resistive layer to be removed that are not desired in the circuit structure. Preferably, substrates 12, 18 and resistive layer 14 are selectively etched. That is, the solution used to etch substrates 12, 18 does not etch resistive layer 14, and the solution used to etch resistive layer 14 does not etch substrates 12, 18.

Laser ablation may be performed by using a laser to selectively thermally remove material from any or all of the layers of the passive electrical article. Photolithography and laser ablation may be used in combination.

The thickness of the electrically insulative layer 16 may limit how the passive electrical article of the present invention can be patterned because the insulative layer 16 itself may not mechanically support the substrates 12, 18. The electrodes may be patterned into substrates 12, 18 such that at least one of the substrates 12, 18 will always support the passive electrical article. The first substrate 12 of the passive electrical article may be patterned and the second substrate 18 may remain continuous (or unpatterned) so that the passive electrical article has “structural integrity”, i.e., the article is capable of being handled without a carrier for support and remains free-standing. Typically, the passive electrical article is double patterned, i.e., patterned on both sides, without the use of a support, provided the passive electrical article has structural integrity.

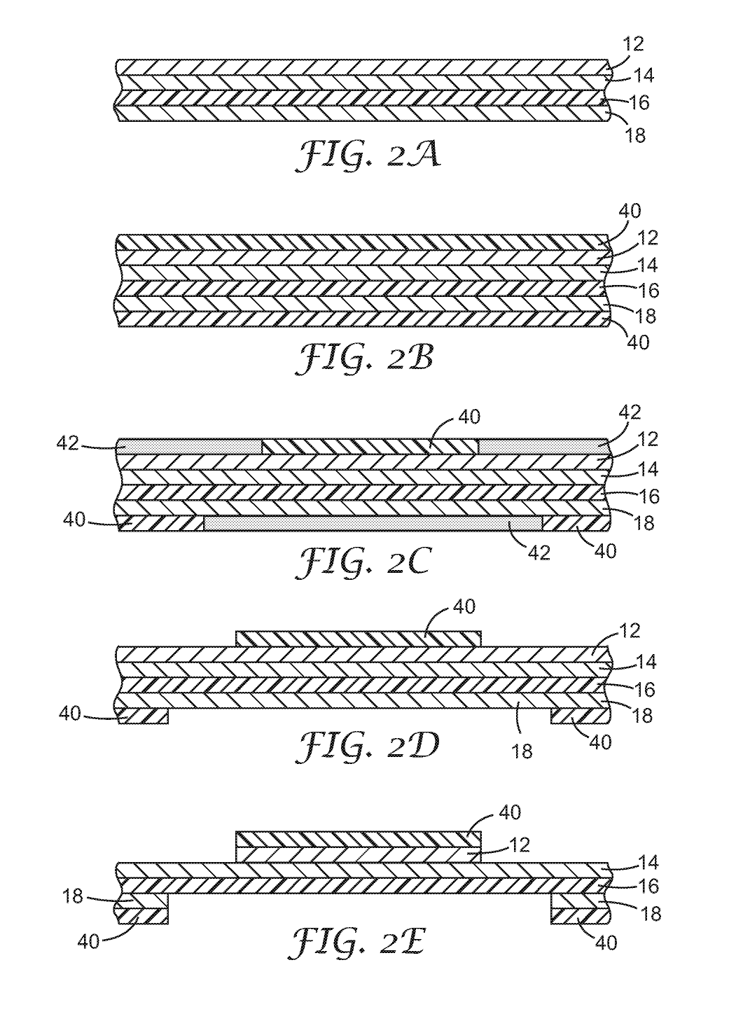

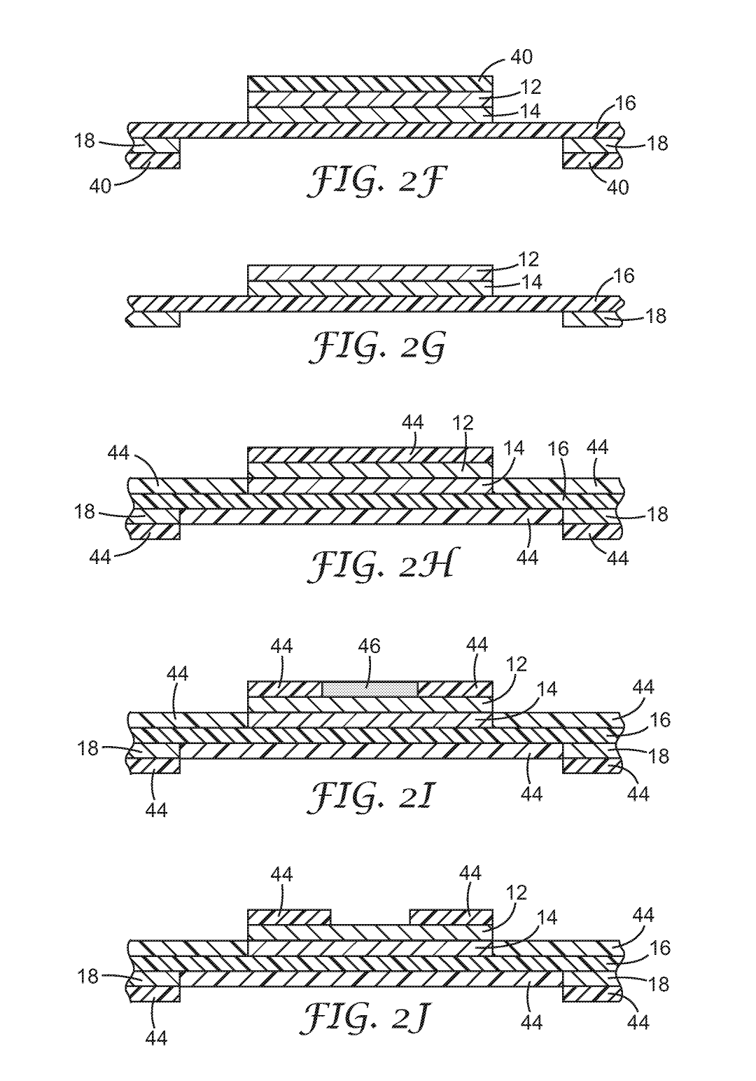

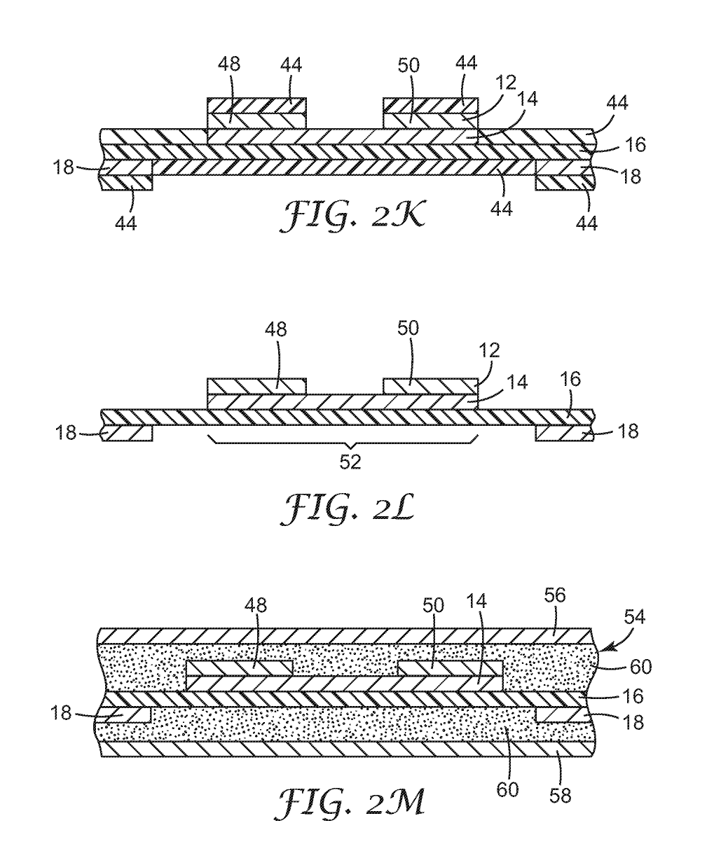

FIGS. 2A-2M illustrate steps in an exemplary photolithography process for forming a resistor from the passive electrical article 10 as illustrated in FIG. 1A or 1C. A passive electrical article 10 comprising a laminate of first conductive substrate 12, electrically resistive layer 14, electrically insulative layer 16, and second conductive substrate 18 is provided (FIG. 2A), and a photoresist 40 is applied to the conductive substrates 12, 18 (FIG. 2B). Selected portions of the photoresist 40 are exposed, such as by exposure to ultraviolet light (FIG. 2C), and the photoresist 40 is developed to remove the unexposed portions 42 of the photoresist (FIG. 2D). A first etching solution is used to etch the revealed portions of conductive layers 12, 18 (FIG. 2E), and a second etching solution is used to etch revealed portions of resistive layer 14 (FIG. 2F). However, it should be noted that for some resistive materials, the same etchant can be used for both the conductor and resistive material. The photoresist 40 is stripped from the article (FIG. 2G), and a new layer of photoresist 44 is applied to the now revealed surfaces (FIG. 2H). The new layer of photoresist 44 is selectively exposed (FIG. 21), and the photoresist 44 is developed to remove the unexposed portions 46 of the photoresist (FIG. 2J). The revealed portions of conductive substrates 12, 18 are etched (in the example, only portions of substrate 12 are revealed) to define two separate electrodes 48, 50 (FIG. 2K), and the photoresist is again stripped (FIG. 2L). A resistor 52 is now defined between electrodes 48, 50 in conductive substrate 12. Finally, the patterned article having resistor 52 is laminated into a printed circuit 54, such as a printed circuit board (FIG. 2M). The conductive substrates 12, 18 of the article 10 are insulated from conductive layers 56, 58 of the printed circuit board 54 by dielectric material 60. Electrodes 48, 50 may be selectively connected to conductive layers 56, 58 by conductive vias (not shown), as is known in the art.

It should be noted that FIGS. 2E and 2F, in which the conductive substrate layers 12, 18 and resistive layer 14 are etched, respectively, could in another embodiment, be switched with FIG. 2K, in which conductive substrate layers 12, 18 are etched. Additional steps (such as cleaning to promote resist adhesion, baking to remove moisture, providing a copper surface treatment to improve the outside conductor surface to the adjoining dielectric, etc. can also be performed at appropriate locations in the process. Different types of passive electrical devices, including capacitors, resistors, inductors and combinations thereof may be formed using similar techniques. Additionally, processes such as laser trimming can be performed if precise tolerances are required for the resistor.

### Circuit Article

The passive electrical article of the present invention itself may function as a circuit article, with some modification. In one instance, the passive electrical article 10 may be patterned. In this instance, a circuit article may be prepared by providing a passive electrical article 10 of the present invention and patterning the passive electrical article 10 as described above to provide a contact for electrical connection. Either one or both substrates 12, 18 of the passive electrical article 10 are patterned to allow access to each surface of the first and second substrates 12, 18, and to provide a through-hole contact.

In another embodiment, a circuit article may be prepared by a method comprising the steps of providing a passive electrical article 10 of the present invention, providing at least one electrical contact, and connecting the contact to at least one substrate 12, 18 of the passive electrical article 10.

A passive electrical article of the present invention may further comprise one or more additional layers, for example, to prepare a printed circuit board or flexible circuit. The additional layer(s) may be rigid or flexible. Exemplary rigid layers include fiberglass/epoxy composite commercially available from Polyclad, Franklin, N.H., under the trade designation PCL-FR-226, ceramic, metal, or combinations thereof. Exemplary flexible layers comprise a polymer film such as polyimide or polyester, metal foils, or combinations thereof. Polyimide is commercially available from E.I. DuPont de Nemours Company, Wilmington, Del., under the trade designation KAPTON and polyester is commercially available from 3M Company, St. Paul, Minn., under the trade designation SCOTCHPAR. These additional layers may also contain electrically conductive traces on top of the layer or embedded within the layer. The term “electrically conductive traces” refers to strips or patterns of a conductive material designed to carry current. Examples of suitable materials for an electrically conductive trace include copper, aluminum, tin solder, silver paste, gold, and combinations thereof.

In this embodiment, a preferred method of making a circuit article comprises the steps of providing a passive electrical article of the present invention, patterning at least one substrate 12, 18 of the passive electrical article, providing an additional layer, attaching the layer to the passive electrical article 10, and providing at least one electrical contact to at least one substrate 12, 18 of the passive electrical article. Preferably, a second additional layer is provided and attached to the passive electrical article.

### Printed Wiring Boards and Flexible Circuits

A passive electrical article of the present invention can be used in a printed circuit board or a flexible circuit, as a component, which functions as a capacitor, a resistor, an inductor, or any combination thereof. The passive electrical article may be embedded or integrated in the printed circuit board or flexible circuit.

A PCB typically comprises two layers of material, for example, a laminate of epoxy and fiberglass, which may have one or two copper surfaces, sandwiching a layer of adhesive or prepreg (the layer of prepreg can have more than one prepreg “layer”). A flexible circuit typically comprises a flexible layer, for example, a polyimide layer coated with copper, and a layer of adhesive on the polyimide. The position of a passive electrical article of the present invention in any suitable PCB or flexible circuit and the process of embedding or integrating a passive electrical article of the present invention in any suitable PCB or flexible circuit are well understood in the art. Notably, with either a PCB or flexible circuit, care must be taken to align the PCB or flexible circuit layers/components.

As noted above, the thickness of the electrically insulative layer 16 may determine how the article 10 can be patterned. When the passive electrical article 10 is incorporated in a PCB or flexible circuit, the PCB or flexible circuit layers may lend further support to the passive electrical article allowing for additional unique patterning techniques.

For example, a double patterning and lamination process may be useful. The double patterning and lamination process comprises the following steps that can occur after the photolithographic patterning one of the substrates 12, 18 as described above. In this process, the patterned substrate is laminated to a supportive material such as a circuit board layer, for example, FR4, with the patterned side facing the supportive material. The other substrate can be patterned by an essentially similar technique, since the electrically insulative layer 16 and the patterned substrates are now fully supported by the supportive material. A second lamination on the exposed side of the second substrate is then conducted to complete the process.

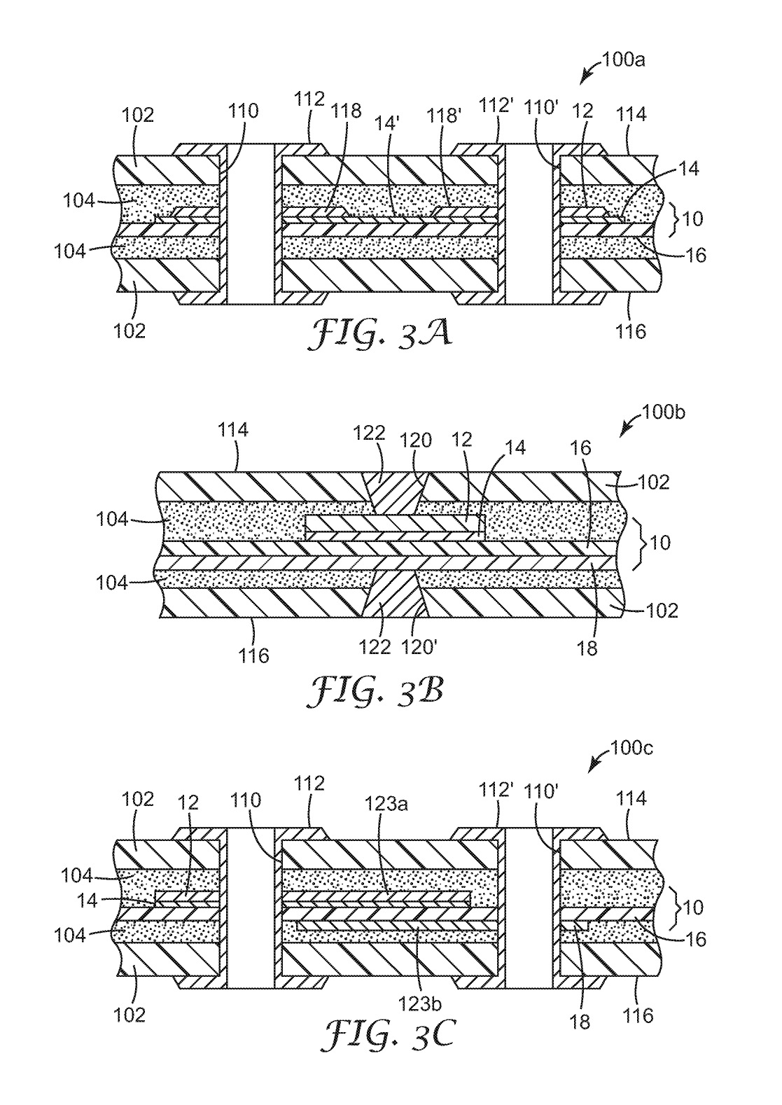

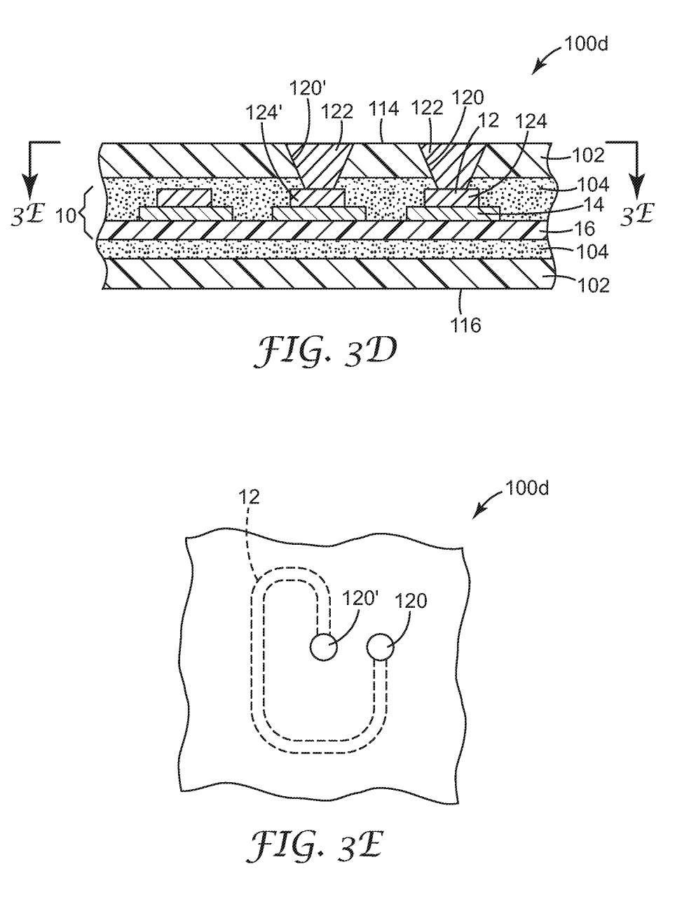

FIGS. 3A-5D illustrate examples of the passive electrical articles of FIGS. 1A-1C patterned to form capacitors, resistors, inductors, and various combinations thereof.

FIGS. 3A through 3C illustrate examples of a PCB 100a, 100b, 100c, respectively, having embedded therein a patterned passive electrical article of FIG. 1A or 1C, in which a single resistive layer 14 is provided. PCB 100a, 100b, 100c, each comprise two layers 102 of a material such as epoxy/fiberglass sandwiching layers 104 of insulative adhesive or prepreg, and a passive electrical article 10 of the present invention, which functions as a resistor in FIG. 3A, a capacitor in FIG. 3B, and an inductor in FIG. 3D. The embodiments of FIGS. 3A-3D are illustrative only, and not intended to be limiting. In other embodiments, for example, one or both of layers 102 may be omitted.

FIG. 3A illustrates PCB 100a containing a passive electrical article 10 of the present invention, which functions as a resistor. In FIG. 3A, signals or current are routed through PCB 100a by through-holes 110 and 110′, which are made conductive by, for example, electroplating with copper to form surface copper structures 112 and 112′, respectively. Surface copper structures 112, 112′ route signals between conductive traces (not shown) on either upper surface 114 or lower surface 116 of PCB 100a. First and second substrates 12, 18 and resistive layer 14 are patterned to form pads 118 and 118′ that cover part of resistive layer 14. (Second substrate 18 has been completely removed in the illustrated area of the passive article 10). Pads 118, 118′ are joined by a portion 14′ of resistive layer 14. Surface copper structures 112, 112′ are used to contact pads 118, 118′, respectively, so that a controlled resistance can be measured between pads 118, 118′, based on the geometry (length and width) of the portion 14′ of resistive layer 14 between the two pads 118, 118′. In other embodiments, different structures and method for making electrical connection with pads 118, 118′ may be utilized, including, for example, blind conductive vias. In other embodiments, pads 118, 118′ are electrically connected to a trace within the interior of the PCB. In other embodiments, layers 102, 104 comprise flexible materials, such that the completed circuit article is flexible.

FIG. 3B illustrates PCB 100b containing a passive electrical article 10 of the present invention, which functions as a capacitor. In FIG. 3B, signals or current are routed through PCB 100b by vias 120 and 120′, which are made conductive by, for example, filing the vias 120, 120′ with a conductive material 122 or electroplating, such as with copper. Conductive vias 120, 120′ route signals between conductive traces (not shown) on either upper surface 114 or lower surface 116 of PCB 100b. First and second substrates 12, 18 and resistive layer 14 are patterned to form capacitive plates on either side of insulative layer 16. In other embodiments, different structures and method for making electrical connection with pads conductive substrates 12, 18 may be utilized. In other embodiments, conductive substrates 12, 18 are electrically connected to a trace within the interior of the PCB. In other embodiments, layers 102, 104 comprise a flexible materials, such that the completed circuit article is flexible.

FIG. 3C illustrates another embodiment of a passive electrical article 10 of the present invention, which functions as a capacitor. In FIG. 3C, signals or current are routed through PCB 100c by through-holes 110 and 110′, which are made conductive by, for example, electroplating with copper to form surface copper structures 112 and 112′, respectively. Surface copper structures 112, 112′ route signals between conductive traces (not shown) on either upper surface 114 or lower surface 116 of PCB 100c. First and second substrates 12, 18 and resistive layer 14 are patterned to form capacitive plates 123a, 123b on either side of insulative layer 16. In other embodiments, different structures and method for making electrical connection with pads conductive substrates 12, 18 may be utilized. In other embodiments, conductive substrates 12, 18 are electrically connected to a trace within the interior of the PCB. In other embodiments, layers 102, 104 comprise a flexible materials, such that the completed circuit article is flexible.

FIGS. 3D and 3E illustrates PCB 100c containing a passive electrical article 10 of the present invention, which functions as an inductor. In FIG. 3D, signals or current are routed through PCB 100d by vias 120 and 120′, which are made conductive by, for example, filing the vias 120, 120′ with a conductive material 122 or electroplating, such as with copper. Conductive vias 120, 120′ route signals between conductive traces (not shown) on either upper surface 114 or lower surface 116 of PCB 100d. First and second substrates 12, 18 and resistive layer 14 are patterned to form a coiled inductive element on one side of insulative layer 16 having contact pads 124, 124′. (Second substrate 18 has been completely removed in the illustrated area of the passive article 10). In one embodiment, resistive layer 14 is a high permeability material, such as a ferrite material, and is patterned to extend at least partially between the patterned coils of conductive substrate 12, such that the high permeability material is in the core of the inductive coil, thus providing a higher inductance for the inductor. In another embodiment, the resistive layer 14 has the same width as the conductive substrate 12. Conductive vias 120, 120′are used to electrically connect with pads 124, 124′, respectively. In other embodiments, different structures and method for making electrical connection with pads 124, 124′ may be utilized. In other embodiments, pads 124, 124′ are electrically connected to a trace within the interior of the PCB. In other embodiments, layers 102, 104 comprise a flexible materials, such that the completed circuit article is flexible.

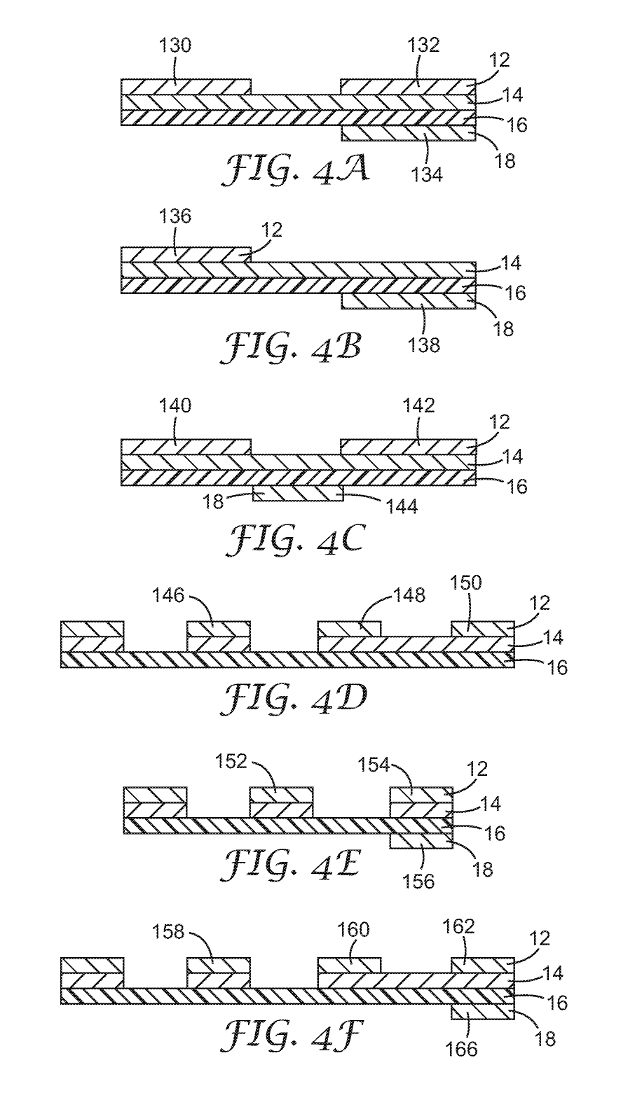

FIGS. 4A through 4F are illustrative examples of how a passive electrical article of FIG. 1A or 1C, in which a single resistive layer 14 is provided, can be patterned to provide a variety of electrical elements, and in particular a variety combined passive circuit elements. For purposes of clarity, the patterned articles are not shown embedded in a PCB or flexible circuit, as with FIGS. 3A-3C above. However, it is to be understood that the patterned articles of FIGS. 4A-4F are intended for such use.

FIG. 4A illustrates a resistor in series with a capacitor. A resistive element is formed between conductive pads 130 and 132, as described with reference to FIG. 3A above. A capacitive element formed between conductive pads 132 and 134, as described with reference to FIG. 3B above.

FIG. 4B illustrates another embodiment of a resistor in series with a capacitor. Both the resistive element and the capacitive element are formed between conductive pads 136 and 138. Because the conductive pads 136, 138 are offset from each other, the resistive layer 14 (which is also conductive, but less conductive than substrates 12, 18), acts both as a resistive element, and also as an extension of the capacitive plate of conductive pad 136.

FIG. 4C illustrates yet another resistive-capacitive structure. A resistive element is formed between conductive pads 140 and 142. The resistive material layer 14 forms the top electrode for a capacitor, the bottom electrode of the capacitor being conductive pad 144.

FIG. 4D illustrates an inductor in series with a resistor. An inductive element is formed between conductive pads 146, 148, and a resistive element is formed between conductive pads 148, 150.

FIG. 4E illustrates an inductor in series with a capacitor. An inductive element is formed between conductive pads 152, 154, and a capacitive element is formed between conductive pads 154, 156.

FIG. 4F illustrates an inductor in series with a resistor and a capacitor. An inductive element is formed between conductive pads 158, 160, a resistive element is formed between conductive pads 160, 162, and a capacitive element is formed between conductive pads 162 and 166. Resistive, capacitive and inductive elements can also be connected in parallel to each other if desired.

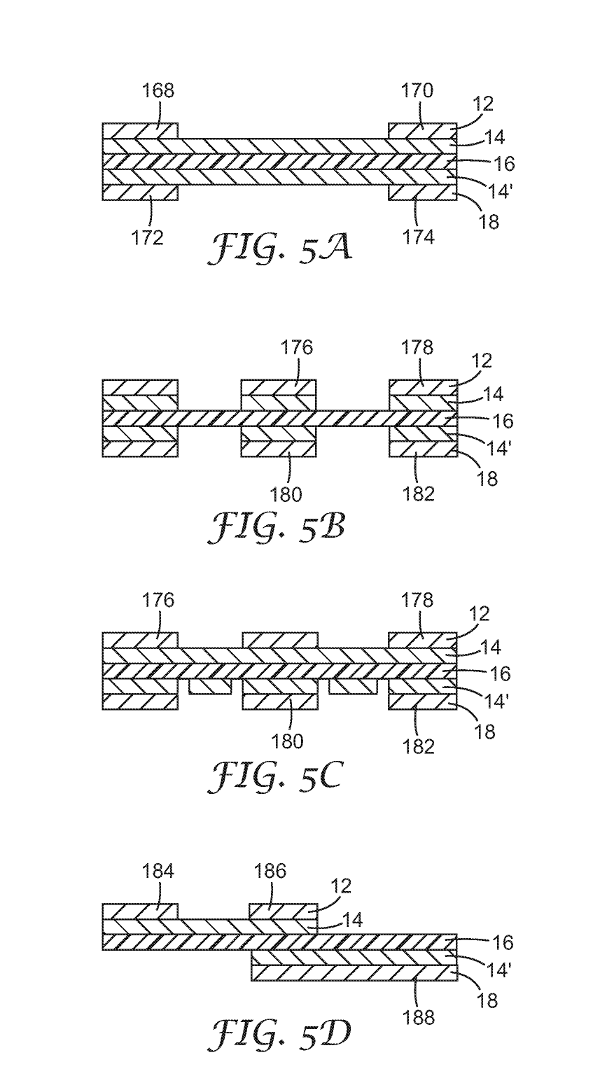

FIGS. 5A through 5D are illustrative examples of how a passive electrical article of FIG. 1B, in which a resistive layer 14 is provided on each substrate 12, 18, can be patterned to provide a variety of electrical elements, and in particular a variety of combined passive circuit elements. For purposes of clarity, the patterned articles are not shown embedded in a PCB or flexible circuit, as with FIGS. 3A-3C above. However, it is to be understood that the patterned articles of FIGS. 5A-5D are intended for such use.

FIG. 5A illustrates an article having a resistor on both sides of insulative layer 16. Separate resistive elements are formed between conductive pads 168, 170, and between conductive pads 172, 174. In this manner, a plurality of passive elements may be positioned within the same X-Y area of a printed circuit. These resistive elements can be electrically isolated from each other, or if desired, they can be connected in series or parallel to each other.

FIGS. 5B and 5C illustrate an article having an inductor on both sides of insulative layer 16. Separate inductive elements are formed between conductive pads 176, 178, and between conductive pads 180, 182. In the article of FIG. 5C, resistive layers 14, 14′ are a high permeability material and extend between the coils of the conductive layers 12, 18, to provide higher inductance. The high permeability material of resistive layers 14, 14′ can be either electrically connected to the conductive coils of the inductor, or electrically isolated from the conductive coils. For example, FIG. 5C illustrates the high permeability material of layer 14 electrically connected to the conductive coils of layer 12, and the high permeability material of layer 14′ electrically isolated from the conductive coils of layer 18.

FIG. 5D illustrates a resistor in series with a capacitor. A resistive element is formed between conductive pads 184, 186, and a capacitive element is formed between conductive pads 186, 188.

The present invention also encompasses an electrical device comprising a passive electrical article of the present invention functioning as an electrical circuit of a PCB or flexible circuit, which comprises a passive electrical article in accordance with the present invention. The electrical device may include any electrical devices, which typically employs a PCB or flexible circuit having a capacitive or resistive component. Exemplary electrical devices include cell phones, telephones, fax machines, computers, printers, pagers, and other devices as recognized by one skilled in the art. The passive electrical article of the present invention is particularly useful in electrical devices in which space is at a premium.

This invention is illustrated by the following examples, but the particular materials and amounts thereof recited in these examples, as well as other conditions and details should not be construed to unduly limit this invention.

### Example 1

A dispersion of 0.3 micron barium titanate in methyl ethyl ketone/methyl isobutyl ketone was prepared in a commercial bead mill using a polyester/polyamine copolymer dispersant. Sufficient epoxy binder solution (EPON 1001F plus EPON 1050) was added to give a volume ratio of barium titanate to epoxy of 45:55. The resulting dispersion (solids content of 60% w/w) was coated using a gravure coater onto 35 micron (one ounce) copper foil which had been previously coated with a <1 um doped platinum resistor layer, with a nominal resistivity of 1000 ohms per square, having the trade designation INSITE and obtained from Rohm & Haas Electronic Materials, Marlborough, Mass. After drying, the barium titanate/epoxy layer was 5 to 6 microns thick. A second sample of 35 micron copper foil, which had no resistor layer, was also coated using the same conditions. The two coatings were laminated, coated side to coated side, in a roll laminator set at approximately 135° C. and 5.93×10⁻³ m/s (14 inches per minute (ipm)). The laminate was cured in an oven at 190° C. for four hours.

The adhesion of the cured laminate was measured using a 90 degree peel test. The adhesion of the resistive material to the dielectric was at least 3.156 kN/m (6 pounds per linear inch (ph)). The adhesion of the resistive material to its copper substrate was at least 3.156 kN/m (6 pli) as well, since the failure was at the resistive-dielectric interface and not at the resistive-copper interface. The adhesion of the dielectric to copper was approximately 1.578 kN/m (3 pli). The adhesion of the cured laminate was also tested after an additional 4 hour, 190° C. thermal bake (to simulate two lamination cycles in the PCB process). There were no significant changes in adhesion for any of the interfaces.

The electrical properties of the cured laminate were also tested. Capacitor and resistor structures were patterned into the conductive and resistive material using photolithographic methods well known in the art. The resistance and capacitance were measured on an LCR meter at 1 kHz frequency. The resistivity was found to be approximately 1000 ohms per square on average. Thus, there was no significant change in resistivity due to the fabrication of the laminate or the patterning process. The capacitance was measured and found to be approximately 0.0155 nF/mm² (10 nF/in²). The change in capacitance over the temperature range of 23° C. to 180° C. and back to 23° C. was also measured. There was less than a 15% increase in capacitance over the 23° C. to 180° C. range. When the sample was returned to 23° C., there was no net change in capacitance.

### Example 2

The same process and materials as above was used to coat a 5 to 6 um thick dielectric layer on 35 um (one ounce) copper foil. Following this, two of these layers were laminated, coated side to coated side, in a hot roll laminator at approximately 135° C. and 5.93×10⁻³ m/s (14 ipm). One of the two copper foils was peeled away from the laminated structure which resulted in its dielectric coating being transferred to the other dielectric coated copper. The dielectric coated copper substrate (now with a dielectric thickness of approximately 10-11 um) was then laminated to an 18 um (one-half ounce) copper foil with a <1 um sputtered nickel-chromium resistive material (dielectric side facing the resistive material) with a sheet resistivity of 25 ohms per square. The copper foil with resistive material thereon was Gould TCR resistive conductor material available from Gould Electronics, Inc., Chandler, Ariz. The laminate was cured at 190° C. for four hours.

The adhesion of the laminate was measured using a 90 degree peel angle. The adhesion of the resistive material to the dielectric was found to be at least 3.156 kN/m (6 pli). As in Example 1, the adhesion of the resistive material to its copper substrate was at least 3.156 kN/m (6 pli) as well, since the failure was at the resistive-dielectric interface and not at the resistive-copper interface. The copper to dielectric adhesion was found to be approximately 2.104 kN/m (4 pli). The adhesion of the cured laminate was also tested after an additional 4 hour, 190° C. thermal bake (to simulate two lamination cycles in the PCB process). There were no significant changes in adhesion for any of the interfaces.

The electrical properties of the cured laminate were also tested. Capacitor and resistor structures were patterned into the conductive and resistive material using photolithographic methods well known in the art. The resistance and capacitance were measured on an LCR meter at 1 kHz frequency. The capacitance was measured to be about 0.0155 nF/mm² (10 nF/in²). The sheet resistivity of the laminate measured to be approximately 25 ohms per square.

### Example 3

Dielectric material of the same formulation as in Examples 1 and 2 was coated on 35 um (one ounce) copper foil using a similar process as stated in Examples 1 and 2, with the exception that the thickness of the dielectric coating was approximately 8 um. In this case, the cured laminate was made by laminating and curing the dielectric coated copper foil and a 35 um copper foil with a <1 um thick, plated nickel-phosphorous resistive material (dielectric side facing resistive material) with a sheet resistivity of 25 ohms per square. The copper foil with resistive material thereon was OHMEGA-PLY Resistive Capacitive Material available from Ohmega Technologies, Inc., Culver City, Calif. The laminate was cured at 177° C. for two hours at temperature and at a pressure of 2.07×10⁶ N/m⁶ (300 psi) in a vacuum lamination press.

### Example 4

Dielectric material of the same formulation as Examples 1 and 2 was coated on 35 um (one ounce) copper foil using a similar process as stated in Examples 1 and 2, with the exception that the thickness of the dielectric coating was approximately 4 um. The dielectric coated copper foil was laminated to the resistive coated copper foil from Example 3 (dielectric to resistor material) using a hot roll laminator at 135° C., a speed of 305 mm/m (12 ipm) and a roll pressure of 1.03×10⁵ N/m² (15 psi). The copper foil which was originally coated with 4 um thick dielectric was peeled away at an 180 degree angle which transferred the dielectric layer from the copper foil to the resistive surface. This process was repeated on another sample to yield two 4 um thick dielectric coated resistive-conductor material sheets. These two sheets were then laminated dielectric to dielectric to yield a laminate with an 8 m thick dielectric and a resistive layer between the dielectric and each of the two copper foils. The laminate was then cured in an oven for two hours at 180° C.

The adhesion of the laminate was measured using a 90 degree peel angle. The adhesion of the resistive material to the dielectric was found to be approximately at least 2.367 kN/m (4.5 pli). As in Example 1, the adhesion of the resistive material to its copper substrate was at least approximately 2.367 kN/m (4.5 pli) as well, since the failure was at the resistive-dielectric interface and not at the resistive-copper interface.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A passive electrical article comprising:
a first electrically conductive planar substrate having a major surface;
a second electrically conductive planar substrate having a major surface, the major surface of the second substrate facing the major surface of the first substrate;
an electrically resistive planar layer on at least one of the major surface of the first substrate and the major surface of the second substrate; and
an electrically insulative planar layer between the first and second substrates and directly adjacent on one side to the electrically resistive layer and directly adjacent on its other side to the major surface of the first or second electrically conductive layer not having an electrically resistive layer thereon;
wherein the insulative layer has a substantially constant thickness, and wherein at least one of the first substrate, the second substrate, the resistive layer and the insulative layer is patterned to form at least two of a resistor, a capacitor and an inductor.

2. The passive electrical article of claim 1, wherein at least one of the first and second substrates is self-supporting.

3. The passive electrical article of claim 1, wherein the resistive layer has a thickness less than about 2 μm.

4. The passive electrical article of claim 1, wherein either the first substrate or the second substrate comprises a multi-layer laminate.

5. The passive electrical article of claim 4, wherein the laminate comprises a layer of copper and a layer of polyimide.

6. The passive electrical article of claim 1, wherein the major surfaces of the first and second substrates have an average surface roughness less than about 300 nm.

7. The passive electrical article of claim 1, wherein the insulative layer comprises a dried or cured resin comprising epoxy, polyimide, polyvinylidene fluoride, cyanoethyl pullulan, benzocyclobutene, polynorbornene, polytetrafluoroethylene, acrylates, polyphenylene oxide (PPO), cyanate ester, bismaleimide triazine (BT), allylated polyphenylene ether (APPE), or blends thereof.

8. The passive electrical article of claim 7, wherein the insulative layer comprises dielectric particles, conductive particles, or mixtures thereof.

9. The passive electrical article of claim 8, wherein the dielectric particles have a size of less than about 10 μm.

10. The passive electrical article of claim 8, wherein the particles are selected from the group consisting of barium titanate, barium strontium titanate, titanium oxide, lead zirconium titanate, silver, nickel, nickel-coated polymer spheres, gold-coated polymer spheres, tin solder, graphite, tantalum nitrides, and metal silicon nitrides, or mixtures thereof.

11. The passive electrical article of claim 8, wherein a particle loading is 20 to 70% by volume based on the total volume of the insulative layer.

12. A method for forming a passive electrical article, the method comprising:
providing a laminate structure comprising a first electrically conductive substrate having a major surface, a second electrically conductive substrate having a major surface, the major surface of the second substrate facing the major surface of the first substrate, an electrically resistive layer on at least one of the major surface of the first substrate and the major surface of the second substrate, and an electrically insulative layer between the first and second substrates and directly adjacent on one side to the electrically resistive layer and directly adjacent on its other side to the major surface of the first or second electrically conductive layer not having an electrically resistive layer thereon, the insulative layer comprising a polymer having a thickness ranging from about 1 μm to about 20 μm, wherein the insulative layer has a substantially constant thickness, and
patterning at least one of the first substrate, the second substrate, and the resistive layer to form at least two of a resistor, a capacitor and an inductor.

13. The method of claim 12, further comprising embedding the patterned laminate in a printed circuit.

14. The method of claim 13, wherein the printed circuit is a rigid printed circuit board.

15. The method of claim 13, wherein the printed circuit is a flexible circuit.

16. A printed circuit board comprising the passive electrical article of claim 1 embedded therein.

17. The printed circuit board of claim 16, wherein the passive electrical article is patterned to form a resistor and a capacitor.

18. The printed circuit board of claim 16, wherein the passive electrical article is patterned to form a capacitor and an inductor.

19. The printed circuit board of claim 16, wherein the passive electrical article is patterned to form a resistor and an inductor.

20. The printed circuit board of claim 16, wherein the passive electrical article is patterned to form a resistor, a capacitor and an inductor.
